(19) United States
(12) Patent Application Publication
(10) Pub. No.: US 2026/0179884 A1
(43) Pub. Date: Jun. 25, 2026

(54) DOWNSTREAM PORT GASES INTRODUCED INTO PLASMA ABATEMENT SYSTEM

(71) Applicant: Applied Materials, Inc., Santa Clara, CA (US)

(72) Inventor: Joseph VAN GOMPEL, Santa Clara, CA (US)

(21) Appl. No.: 19/000,223

(22) Filed: Dec. 23, 2024

(51) Int. Cl. H01J 37/32

(52) U.S. Cl. CPC H01J 37/32449; H01J 37/32834; H01J 37/32981

(57) ABSTRACT

The present disclosure presents a method for supplying a first gas into a first inlet port disposed in a foreline between a semiconductor processing chamber and a plasma source and supplying a second gas into a second inlet port disposed in the foreline between the plasma source and a vacuum source, where the second gas is one or both of a hydrogen containing gas and an oxygen containing gas.

### BACKGROUND

### Field

Embodiments of the present invention generally relate to abatement systems in semiconductor manufacturing, and, more particularly, to using a downstream port in a plasma abatement system to introduce downstream gases.

### Description of the Related Art

The incorporation of reagents before a plasma abatement system enhances the effectiveness of gas treatment in semiconductor manufacturing processes. By introducing specific reagent gases, such as hydrogen or oxygen, prior to the plasma stage, manufacturers can facilitate the initial breakdown of fluorinated greenhouse gases (F-GHGs) like perfluorocarbons (PFCs) and nitrogen trifluoride (NF₃). This pre-abatement approach allows for the generation of reactive intermediates that improve the efficiency of subsequent plasma reactions, leading to a higher conversion rate of harmful emissions into less hazardous byproducts.

This method not only increases the overall destruction of targeted gases but also optimizes the operational flexibility of the abatement system. Adjustments can be made based on real-time monitoring of gas composition, allowing for the management of reagent flow and enhancing compliance with stringent environmental regulations. Further, the introduction of reagents upstream can reduce energy consumption and operational costs, contributing to a more sustainable semiconductor manufacturing process. However, the introduction of reagents upstream may still cause the emission of harmful gases or hazardous byproducts at the output of the plasma abatement system.

### SUMMARY

The present disclosure presents an upstream port for providing a first reagent gas directly before an abatement system and a downstream port for providing a second reagent directly after the abatement system, where the downstream port introduces, e.g., oxygen or hydrogen to neutralize or treat harmful gases and byproducts produced in the abatement system.

In one example, a method includes supplying a first gas into a first inlet port disposed in a foreline between a semiconductor processing chamber and a plasma source and supplying a second gas into a second inlet port disposed in the foreline between the plasma source and a vacuum source, where the second gas is one or both of a hydrogen containing gas and an oxygen containing gas.

In another example, a method includes supplying a gas into an inlet port disposed in a foreline between a plasma source and a vacuum source and coupling the foreline to at least one of a hydrogen containing gas source or an oxygen containing gas source.

In yet another example, an abatement device includes a plasma reactor, a first conduit coupled to an inlet of the plasma reactor, a reagent source coupled to an upstream injection port of the first conduit, a second conduit coupled to an outlet of the plasma reactor having at least one downstream injection port positioned downstream of the plasma reactor, and a foreline gas injection kit coupled to the second conduit through the at least one downstream injection port, the foreline gas injection kit coupled to at least one of a hydrogen containing gas source or an oxygen containing gas source.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments of the present disclosure and are therefore not to be considered limiting of its scope, and the present disclosure may admit to other equally effective embodiments.

FIG. 1 is a schematic diagram of a processing system, according to an embodiment of the present application.

FIG. 2 illustrates a schematic diagram of the processing system including an abatement system with a downstream port, according to an embodiment of the present application.

FIG. 3 is a flowchart for using a downstream port in the abatement system of FIG. 2, according to an embodiment of the present application.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present examples generally relate to systems and apparatuses of semiconductor manufacturing, and, more particularly, to systems and methods of generating a plasma for semiconductor substrate processing.

Plasma abatement is a process used to neutralize or treat harmful gases and byproducts generated during semiconductor fabrication, especially in etching and deposition processes. During these processes, toxic gases (like fluorinated compounds, volatile organic compounds, and nitrogen oxides) are often released. Plasma abatement systems break down these hazardous emissions using plasma, a high-energy ionized gas. The plasma reacts with these gases to convert them into safer byproducts, such as water, carbon dioxide, and other less harmful compounds, before they are released into the environment. A reagent gas is a chemical gas used in semiconductor processes that actively participates in a chemical reaction to achieve a desired result, such as etching or deposition. In processes like chemical vapor deposition (CVD) or plasma etching, the reagent gas reacts with the surface of the substrate or with other gases to either remove material from the substrate (etching) or deposit new material onto it (deposition). Common reagent gases include oxygen, fluorine-containing gases, and chlorine-based gases, each chosen for specific reactions depending on the material being processed.

Pre-pump plasma abatement system reduce emissions of high-global warming potential (GWP) gases, such as perfluorocarbons (PFCs), nitrogen trifluoride (NF₃), and sulfur hexafluoride (SF₆), which are commonly used in semiconductor manufacturing. The plasma abatement system leverages plasma dissociation technology to treat smaller, concentrated volumes of gas before they are pumped out, minimizing both energy use and harmful emissions like nitrogen oxides (NOx). The benefits of using such plasma abatement system include, by treating gas volumes pre-pump and on-demand, the plasma abatement system consumes less energy compared to traditional post-pump abatement systems that operate continuously. The plasma dissociation process breaks down fluorinated gases into harmless byproducts with near-zero NOx emissions, aligning with strict environmental regulations. The plasma abatement system is highly effective in neutralizing gases like carbon tetrafluoride (CF₄) and octafluorocyclobutane (C₄F₈), helping to significantly reduce greenhouse gas emissions in semiconductor processes.

In the current configuration of the plasma abatement system, reagent gases are usually added before the abatement process takes place. This is beneficial for optimizing the plasma dissociation that occurs within the plasma abatement system. Reagent gases such as hydrogen, oxygen, or water vapor are introduced into the abatement unit to facilitate the breakdown of fluorinated greenhouse gases (F-GHGs) like perfluorocarbons (PFCs) and other hazardous byproducts produced during semiconductor manufacturing. By introducing these reagent gases prior to plasma abatement, the plasma abatement system can effectively dissociate the harmful gases into lower molecular weight compounds, such as hydrogen fluoride (HF). This controlled reaction reduces the likelihood of F-GHG reformation downstream and ensures efficient gas neutralization, minimizing environmental emissions like NOx and other pollutants.

The system's pre-pump design, coupled with the addition of reagent gases at this stage, ensures that the process gas volume remains low and concentrated, which not only optimizes the abatement efficiency but also reduces energy consumption compared to the post-pump system. These systems ionize and break down reactive gases before they are pumped away, minimizing the risk of contamination or environmental harm.

However, issues can arise with emissions post-abatement, which may lead to inefficiencies or environmental compliance problems. Such issues may include incomplete abatement. If the plasma abatement process does not fully neutralize or break down all harmful gases, some hazardous compounds may remain and be emitted post-abatement. Another issue may include formation of secondary byproducts. During plasma treatment, some gases may decompose into unintended secondary byproducts, which may still be harmful. Yet another issue may relate to particulate matter emission. Plasma abatement systems may generate particulate matter, which, if not properly captured, can be released as emissions. Yet another issue may involve chemical residue accumulation. Some reactive gases may form residues that build up inside the abatement chamber over time, reducing efficiency and potentially leading to leaks or unintentional emissions.

To address such issues, the example embodiments present a downstream port or inlet for introducing reagent gases directly after the plasma abatement process. The downstream port or inlet may be positioned directly after the pre-pump or pre-pump abatement system. The upstream port before the pre-pump abatement system provides a first reagent gas and the downstream port directly after the pre-pump abatement system provides a second reagent gas. The second reagent gas interacts with the first reagent gas or with selected unintended secondary byproducts to minimize the environmental impact of the exhaust, keeping compliant with regulatory standards. The choice of the second reagent gas following the abatement process depends on the chemical characteristics and reactivity of the first reagent gas, as well as the target byproducts for neutralization. Stated differently, the second reagent gas is chosen to work synergistically with the first reagent gas to target and neutralize specific byproducts. The second reagent gas can be, e.g., hydrogen or oxygen.

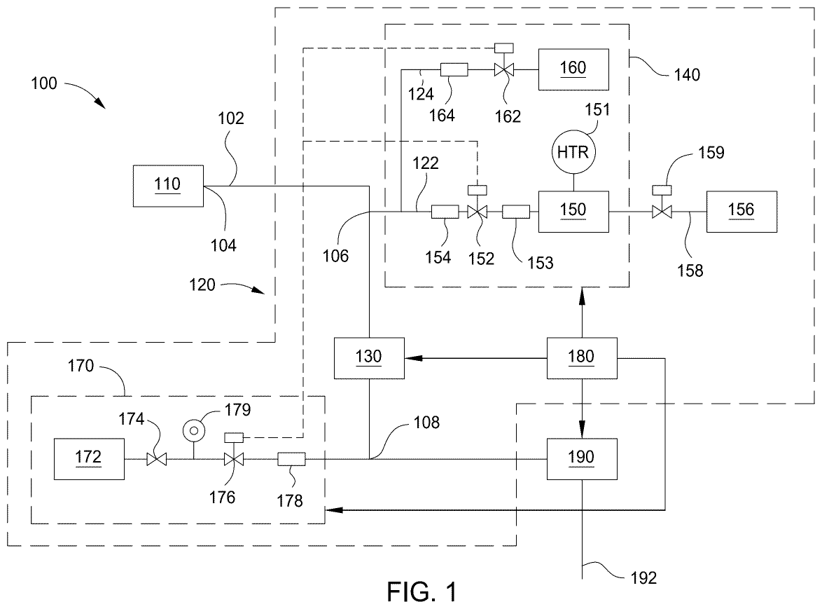

FIG. 1 is a schematic diagram of a processing system, according to an embodiment of the present application.

FIG. 1 depicts a schematic diagram of a processing system 100 in accordance with the implementations disclosed herein. As shown in FIG. 1, the processing system 100 includes a processing chamber 110 coupled with an abatement system 120. The processing chamber 110 has a chamber exhaust port 104 coupled to a foreline 102 of the abatement system 120. A throttle valve (not shown) may be placed proximate the chamber exhaust port 104 for controlling the pressure inside the processing chamber 110. At least a first injection port 106 and a second injection port 108 may be formed in the foreline 102. The abatement system 120 communicates with a vacuum source 190 coupled to a second end of the foreline 102. The vacuum source 190 is external to the abatement system 120. A plasma source 130 is coupled in the foreline 102 at a location between the first injection port 106 and the vacuum source 190.

The processing chamber 110 may be, for example, a processing chamber for carrying out a deposition process, an etching process, an annealing process or a cleaning process, among others. Representative chambers for carrying out a deposition process include deposition chambers, such as, for example, plasma enhanced chemical vapor deposition (PECVD) chambers, chemical vapor deposition (CVD) chambers, or physical vapor deposition (PVD) chambers. In some implementations, the deposition process may be one that deposits dielectrics, such as silicon dioxide, (SiO₂), silicon nitride (SiNx), silicon oxynitride (SiON), crystalline silicon, a-Si, doped a-Si, fluorinated glass (FSG), phosphorous doped glass (PSG), boron-phosphorous doped glass (BPSG), carbon-doped glass, and other low-k dielectrics, such as polyimides and organosiloxanes. In other implementations, the deposition process may be one that deposits metals, metal oxides, or metal nitrides, such as, for example, titanium, titanium dioxide, tungsten, tungsten nitride, tantalum, tantalum nitride, tantalum carbide, aluminum, aluminum oxide, aluminum nitride, ruthenium, or cobalt. In addition, metal alloys may be deposited, such as lithium-phosphorous-oxynitride, lithium-cobalt, and many others. The deposition process performed in the processing chamber 110 may be plasma assisted. For example, the process performed in the processing chamber 110 may be a plasma etch process for etching silicon-based material. In one implementation, the processing chamber 110 is a PECVD chamber for depositing a silicon-based material.

Foreline 102 serves as a conduit that routes effluent leaving the processing chamber 110 to the abatement system 120. The effluent may contain material, which is undesirable for release into the atmosphere or may damage downstream equipment, such as vacuum pumps. For example, the effluent may contain compounds from a dielectric deposition process or from a metal deposition process.

Examples of silicon-containing materials, which may be present in the effluent, include, for example, silicon tetrachloride (SiCl₄) and/or silicon tetrafluoride (SiF₄). The effluent may also include fluorinated compounds (greenhouse gases) and other hazardous gases.

As shown, the abatement system 120 includes the plasma source 130, a reagent delivery system 140, a foreline gas injection kit 170, and a controller 180. Foreline 102 provides effluent leaving the processing chamber 110 to the plasma source 130. The plasma source 130 may be any plasma source coupled to the foreline 102 suitable for generating a plasma therein. For example, the plasma source 130 may be a remote plasma source, an in-line plasma source, or other suitable plasma source for generating a plasma within the foreline 102 or proximate the foreline 102 for introducing reactive species into the foreline 102. The plasma source 130 may be, for example, an inductively coupled plasma source, a capacitively coupled plasma source, a direct current plasma source, or a microwave plasma source. The plasma source 130 may further be a magnetically enhanced plasma source of any kind described above.

A reagent delivery system 140 may also be coupled with the first injection port 106 via a first conduit 122. The reagent delivery system 140 delivers one or more reagents, such as abating reagents, to the foreline 102 upstream of the plasma source 130. In an alternative implementation, the reagent delivery system 140 may be coupled directly to the plasma source 130 for delivering reagents directly into the plasma source 130. The reagent delivery system 140 includes a first reagent source 150 coupled to the foreline 102 (or the plasma source 130) via the first conduit 122. In some implementations, the first reagent source 150 is a low-pressure boiler, and a liquid abating agent, such as liquid water, is disposed in the low-pressure boiler. Alternatively, the first reagent source 150 may be a flash evaporator capable of turning liquid water into water vapor. The first reagent source 150 includes a heater 151 for heating water to form an abating reagent, such as water vapor or steam. An abating reagent in the form of a vapor, such as a water vapor, is injected into the foreline 102 via the first injection port 106. A level sensor may be located in the abating reagent delivery system for providing a signal to the controller 180 that selectively opens a fill valve (not shown) to maintain the water level inside the first reagent source 150.

The first reagent source is coupled with a water source 156 via a third conduit 158 for supplying water to the first reagent source 150. One or more valves 159 may be positioned along the third conduit 158 for controlling the flow of water from the water source 156 to the first reagent source 150.

One or more valves may be positioned along the first conduit 122 between the first reagent source 150 and the first injection port 106. For example, in some implementations, a valve scheme may include a two-way control valve 152, which functions as an on/off switch for controlling the flow the one or more reagents from the first reagent source 150 into the foreline 102, and a flow control device 154, which controls the flow rates of the first reagent source 150 into the foreline 102. The flow control device 154 may be disposed between the foreline 102 and the two-way control valve 152. The two-way control valve 152 may be any suitable control valve, such as a solenoid valve, pneumatic valve, needle valve or the like. The flow control device 154 may be any suitable active or passive flow control device, such as a fixed orifice, mass flow controller, needle valve or the like. In some implementations, a heater 153 is positioned along the first conduit for maintaining the reagent supplied from the first reagent source 150 in vapor form. In some implementations, the heater 153 is positioned along the first conduit 122 in between the two-way control valve 152 and the first reagent source 150.

A representative volatizing abating reagent that may be delivered by the first reagent source 150 includes, for example, H₂O. H₂O may be used when abating effluent containing, for example, CF₄ and/or other materials. H₂O may be provided in liquid, vapor or combination of liquid and vapor. In some implementations, the volatilizing abating reagents may be consumed by the compounds of the effluent, and therefore, may not be considered catalytic.

The reagent delivery system 140 further includes a second reagent source 160 coupled to the foreline 102 (or the plasma source 130) via a second conduit 124 that may join with the first conduit 122, as is commonly done, or it may go directly to the foreline 102. One or more valves are positioned along the second conduit 124 between the second reagent source 160 and the first conduit 122 for controlling the flow of the second reagent. For example, in some implementations, a valve scheme may include a two-way control valve 162, which functions as an on/off switch for controlling the flow the one or more reagents from the second reagent source 160 into the foreline 102, and a flow control device 164, which controls the flow rates of the second reagent source 160 into the foreline 102. The flow control device 164 may be disposed between the foreline 102 and the two-way control valve 162. The two-way control valve 162 may be any suitable control valve, such as a solenoid valve, pneumatic valve, needle valve or the like. The flow control device 164 may be any suitable active or passive flow control device, such as a fixed orifice, mass flow controller, needle valve or the like.

In one example, an oxygen-containing gas may be delivered by the second reagent source 160, for example, O₂. The O₂ may be used when abating effluent containing, for example, CF₄ and/or other materials. In another example, a hydrogen-containing gas may be used in conjunction with or as an alternative to O₂ in one or more implementations. In other examples, other gases may be used, such as, but not limited to, ammonia (NH₃).

The foreline gas injection kit 170 may also be coupled to the foreline 102 upstream or downstream of the plasma source 130 (downstream depicted in FIG. 1). The foreline gas injection kit 170 may controllably provide a foreline gas, such as nitrogen (N₂), argon (Ar), oxygen (O₂), hydrogen (H₂), or clean dry air, into the foreline 102 to control the pressure within the foreline 102. The foreline gas may be comprised of a single type of gas, or a combination of one or more gases. The foreline gas injection kit 170 may include a foreline gas source 172 followed by a pressure regulator 174, further followed by a control valve 176, and even further followed by a flow control device 178. The pressure regulator 174 sets the gas delivery pressure set point. The control valve 176 turns on and off the gas flow. The control valve 176 may be any suitable control valve, such as discussed above for the two-way control valve 152. The flow control device 178 provides the flow of gas specified by the set point of pressure regulator 174. The flow control device 178 may be any suitable flow control device, such as discussed above for the flow control devices 154 and 164.

In some implementations, the foreline gas injection kit 170 may further include a pressure gauge 179. The pressure gauge 179 may be disposed between the pressure regulator 174 and the flow control device 178. The pressure gauge 179 may be used to measure pressure in the foreline gas injection kit 170 upstream of the flow control device 178. The measured pressure at the pressure gauge 179 may be utilized by a control device, such as a controller 180, discussed below, to set the pressure upstream of the flow control device 178 by controlling the pressure regulator 174.

In some implementations, the control valve 176 may be controlled by the controller 180 to turn gas on only when the reagents from the first reagent source 150 and/or the second reagent source 160 is flowing, such that usage of gas is minimized. For example, as illustrated by the dotted line between the two-way control valve 152 of the first reagent source 150 and the control valve 176 of the foreline gas injection kit 170, the control valve 176 may turn on (or off) in response to the two-way control valve 152 being turned on (or off).

The foreline 102 may be coupled to the vacuum source 190 or other suitable pumping apparatus. The vacuum source 190 is coupled with an exhaust line 192 that may be connected to a facility exhaust (not shown). The vacuum source 190 pumps the effluent from the processing chamber 110 to appropriate downstream effluent handling equipment, such as to a scrubber, incinerator or the like. In some implementations, the vacuum source 190 may be a backing pump, such as a dry mechanical pump or the like. The vacuum source 190 may have a variable pumping capacity with can be set at a chosen level, for example, to control or provide additional control of pressure in the foreline 102.

The controller 180 may be coupled to various components of the processing system 100 to control the operation thereof. For example, the controller 180 may monitor and/or control the foreline gas injection kit 170, the reagent delivery system 140, and/or the plasma source 130 in accordance with the teachings disclosed herein. In other examples, the controller 180 can respond to the flow of gases into the process chamber 110 and can monitor and/or control the foreline gas injection kit 170, the reagent delivery system 140, and/or the plasma source 130.

The implementations of FIG. 1 are schematically represented and some components have been omitted for simplicity. For example, a high-speed vacuum pump, such as a turbo molecular pump or the like, may be disposed between the processing chamber 110 and the foreline 102 for removing effluent gases from the processing chamber 110. Additionally, other variants of components may be provided to supply the foreline gas, the reagent, and/or the plasma.

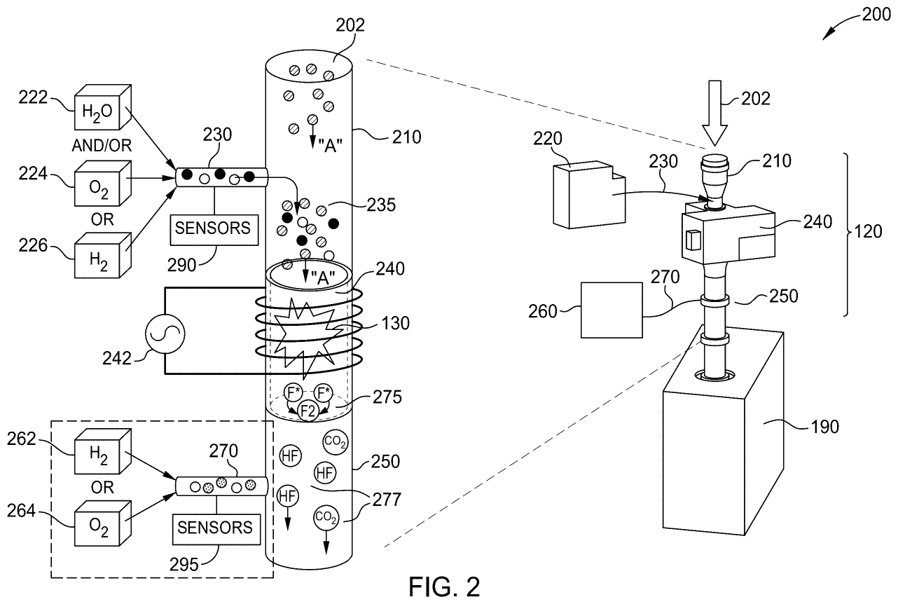

FIG. 2 illustrates a schematic diagram of the foreline 102 of the processing system 100 including the abatement system 120 with a downstream or second injection port 108, according to an embodiment of the present application.

The diagram shows the abatement system 120 (FIG. 1), which includes a first conduit 210 of the foreline 102 for receiving gases 202 (e.g., effluent gas from tool) from the processing chamber 110 (FIG. 1), the plasma source 130, and a second conduit 250 of the foreline 102 that connects the plasma source 130 to the vacuum source 190. The reagent delivery system 140 is connected to the first conduit 210 via the first injection port 106. The first injection port 106 may be referred to as an upstream port (relative to the plasma source 130). The first injection port 106 may supply water (H₂0) (from a water source 222), O₂ (from an oxygen source 224), H₂ (from a hydrogen source 226), or other suitable reagent into the first conduit 210 positioned upstream of the plasma source 130. The gases going through the first injection port 106 interact with the gases 202 traveling in the direction “A.” As such, a mixture of gases 235 enter the plasma source 130 of the abatement system 120. The mixture of gases 235 are processed by the plasma source 130, which is energized by a voltage source 242. In the plasma source 130, gas mixture is disassociated or ionized, resulting in the liberation of species of atomic F+C+H, in one example.

The gases 275 created in the plasma source 130 are generally more desirable than the gases 202 exiting the processing chamber 110, although some of which may still be considered a hazardous gas or undesirable byproduct. To make the gases 275 less hazardous or more desirable for further treatment, the gases 275 are exposed to the foreline gases provided through the second injection port 108 that is connected to the second conduit 250. The second injection port 108 may be referred to as a downstream port (relative to the plasma source 130). The second injection port 108 may supply H₂ (from a hydrogen source 262) or O₂ (from an oxygen source 264) and/or N₂ from a nitrogen source into the second conduit 250 positioned after the plasma source 130 from the foreline gas source 172. The hazardous gases 275 interact with the gases provided by the second injection port 108 (i.e., H₂ or O₂) to produce treated gases 277.

In one example, abatement system 120 converts F₂ into hydrogen fluoride (HF), along with carbon dioxide (CO₂), which are less hazardous under controlled conditions. HF is easier to manage and capture in downstream scrubbers or neutralizers. CO₂ is not generally hazardous in normal outdoor air and is considered minimally toxic by inhalation. In another example, as with F₂, both chlorine (Cl₂) and bromine (Br₂) can be converted to HCl and HBr, respectively. As such, both Cl₂ and Br₂ can be effectively converted to HCL and HBr, respectively, through the same addition of H₂.

Therefore, when process gases include high levels of O₂ in the process chamber with CF₄ or related CxFy gases, significant F₂ is formed along with CO, CO₂, and COF₂. F₂ is reactive and corrosive. The addition of H₂ downstream of the plasma reactor forms HF, which is less corrosive and toxic than F₂, and is more readily scrubbed in the facility exhaust scrubbers (not shown). Reaction of the process gas nitrogen trifluoride (NF₃) in plasma (either in the process chamber or in the post-pump plasma) also generates significant F₂, which can be converted to HF by addition of H₂. In another example, utilization of H₂ in place of H₂O addresses a number of operational and engineering issues. However, excess H₂ in the foreline after the plasma is a potential safety issue. The addition of an appropriate amount of O₂ post-plasma can convert excess H₂ to harmless water vapor.

The second injection port 108, which may already be part of a typical installation, is positioned or disposed directly after the plasma source 130. The second injection port 108 supplies one or more foreline gases (i.e., H₂ (262) or O₂ (264) or oxygen containing gas or hydrogen containing gas), or even N₂ or nitrogen containing gas, in some examples. The choice of the one or more reagents comprising the foreline gas may depend on the nature of the remaining gases. The one or more reagents should not interfere with the vacuum system or create excessive byproducts that may need further treatment. In other words, the one or more reagents depend on the chemical characteristics and reactivity of the first reagent gas(es), as well as the target byproducts for neutralization. The choice of the foreline gas following the abatement plasma process depends on the chemical characteristics and reactivity of the first reagent gas, as well as the target byproducts for neutralization. Stated differently, the second reagent gas of the foreline gas is chosen to work synergistically with the first reagent gas to target and neutralize specific byproducts. After abatement, the exhaust is still hot, thus allowing the second reagent gas to react efficiently with any residual or transformed byproducts.

In one example, the one or more reagents comprising the foreline gas may include O₂. Injecting oxygen downstream of the abatement system 120 leverages the heat of the exhaust to promote the rapid reaction of residual hydrogen (H₂) with the oxygen (O₂) to form water vapor (H₂O), neutralizing potentially flammable hydrogen gas. Thus, the byproduct is H₂O vapor, which is environmentally benign and easily vented. The conversion to water vapor minimizes the environmental impact of the exhaust, keeping compliant with regulatory standards. In some examples, the second injection port 108 may be located directly after the plasma source 130, before temperatures of the gases 275 significantly drop, thus promoting the efficiency of the reaction between the gases 275 and the foreline gases provided through the second injection port 108. The rate of the O₂ may be calibrated based on the concentration of the H₂ in the exhaust stream to avoid excessive O₂ that may alter downstream processes. Also, gas sensors for H₂ and O₂ concentrations may be placed downstream to ensure complete reaction and prevent any accumulation of unreacted gases.

In one example, the one or more reagents comprising the foreline gas may include H₂. Injecting hydrogen downstream of the plasma source 130 is useful in reducing fluorine (F₂), which is toxic and corrosive. This configuration converts the F₂ into hydrogen fluoride (HF), which is less hazardous under controlled conditions. HF is easier to manage and capture in downstream scrubbers or neutralizers. The second injection port 108 allows mixing with the gases 275 while the gases 275 are still hot, which enhances the reduction of F₂. A controlled and metered H₂ injection system, with real-time gas sensors, ensures accurate dosing to efficiently reduce the amount of F₂ in the effluent stream. Continuous monitoring of F₂, H₂, and HF levels ensures that the reaction proceeds safely and F₂ is neutralized. As such, converting F₂ to HF significantly reduces the toxic impact of the exhaust, as HF is less reactive and more manageable.

In one example, CF₄ and O₂ in process chamber results in F₂ being present in exhaust entering the foreline 102. The addition of H₂O upstream of the plasma source 130 reduces the amount of F₂ present in the gases 275, and the addition of H₂ as a foreline gas downstream of the plasma source 130 further reduces F₂ the amount of F₂ present in the second conduit 250 and eventually reaching the vacuum source 190. In yet another example, NF₃ in process chamber results F₂ in the exhaust entering the foreline 102. The addition of H₂O and O₂ can be utilized to remove F-GHGs during, e.g., the etch step and the addition of H₂ post-plasma can further reduce F₂. In yet another example, H₂ may be used to abate F-GHG gases (CF₄, C₄F₈, etc.) in place of H₂O reagent. The addition of O₂ post-plasma can remove excess H₂ from the foreline for safety purposes and O₂ can be interlocked to H₂ to prevent H₂ buildup in duct.

Therefore, the second injection port 108 (downstream port) provides a location for introducing one or more reagents post-abatement, allowing for further reactions with residual gases. This flexibility enables adjustments to reagent types and flow rates based on the specific gas composition detected at this stage. For instance, injecting hydrogen or oxygen (at the downstream port) can assist in converting remaining fluorinated gases into non-hazardous products.

In one example, the second injection port 108 (downstream port) can be integrated with gas analysis equipment to continuously monitor the composition of gases exiting the abatement system 120. By analyzing the exhaust stream in real-time, operators can identify any remaining hazardous compounds and implement targeted treatment measures.

By facilitating additional gas treatment downstream, the abatement system 120 can better address emissions that may still pose environmental risks. The second injection port 108 (downstream port) may be coupled with various abatement technologies, such as catalytic converters or scrubbers (not shown), to ensure that the exhaust meets stringent environmental standards before entering the atmosphere.

The second injection port 108 (downstream port) can seamlessly integrate with the abatement system 120 and support existing gas delivery and analysis systems. Enhanced monitoring systems at the second injection port 108 can also be used to provide real-time feedback and ensure that emissions are effectively managed. This may involve deploying advanced sensors and data analytics tools. The abatement system 120 also facilitates easy access for maintenance and troubleshooting to ensure that the second injection port 108 and its associated systems operate efficiently over time.

The first injection port 106 may be coupled to first sensors 290 and the second injection port 108 may be coupled to second sensors 295.

The first sensors 290 and the second sensors 295 may be gas composition sensors. In one example, Fourier transform infrared (FTIR) spectroscopy techniques may be used. FTIR sensors provide a broad analysis of gases (like CF₄, HF, H₂O, C₄F₈, CHF₃, etc.) by identifying unique absorption spectra. FTIR provides real-time, continuous monitoring with high accuracy, especially for multi-gas applications in complex mixtures. The FTIR sensors may be located near both upstream and downstream ports to verify complete reaction of pollutants and reagents.

In another example, mass spectrometers may be used for precise, low-concentration measurements of specific gases such as trace F2 or residual H2, especially useful downstream to verify abatement effectiveness. Mass spectrometers can detect very low levels of gases, with the capability to differentiate between isotopes if needed. Mass spectrometers may be placed downstream to verify the complete reaction of primary and secondary reagents.

In another example, electrochemical sensors may be used for monitoring specific gases like H2, O2, HF, and F2 in both upstream and downstream locations. Electrochemical sensors have fast response times and are cost-effective for detecting individual gas concentrations. Electrochemical sensors may be placed in pairs near each port to detect reactive gases and verify abatement efficiency.

In another example, photoionization detectors (PIDs) may be used to detect volatile organic compounds (VOCs) or other toxic intermediates formed upstream, often before full abatement. PIDs have a high sensitivity to low-concentration organics or specific reactive intermediates and can be placed upstream to detect VOCs early in the exhaust stream and avoid accumulation.

In another example, temperature sensors may be used, such as thermocouples and infrared (IR) temperature sensors. Thermocouples monitor gas temperature at both upstream and downstream points to ensure reaction temperatures are optimal and consistent. Thermocouples have fast response times and are suitable for high-temperature applications. Thermocouples can be installed directly near injection ports and abatement chambers to track temperature changes from exothermic reactions.

In another example, flow sensors may be used, such as mass flow meters, thermal flow sensors, and differential pressure flow meters. Mass flow meters can measure the rate of gas entering and exiting the abatement system 120, providing insight into the balance of reagent gas injections and the exhaust rate. Mass flow meters can handle both high-pressure and low-pressure conditions, and may be installed on reagent gas lines and exhaust lines upstream and downstream to maintain accurate injection and exhaust flow control. Thermal flow sensors measure gas flow rates by detecting changes in heat transfer caused by gas movement, ideal for upstream monitoring to adjust reagent gas flow. Thermal flow sensors are sensitive to low flow rates and compatible with corrosive or reactive gases, and may be positioned upstream for precise control of reagent gas delivery. Differential pressure flow meters may be used to assess pressure drops across the abatement unit, indicating if gas flow needs adjustment and can be installed at entry and exit points of the abatement device to monitor pressure changes that reflect flow or blockage issues.

In another example, pressure sensors may be used such as piezoelectric pressure sensors and capacitive pressure sensors. Piezoelectric pressure sensors measure absolute or differential pressure, useful for upstream monitoring of gas injection pressure. Capacitive pressure sensors measure pressure changes downstream, monitoring pressure buildup or release after reactions.

In another example, safety sensors may be used such as hydrogen leak detectors and oxygen leak detectors. These sensors ensure safe levels of hydrogen or oxygen when using H₂ or O₂ are reagents, respectively. Alarms or notifications may be triggered if the hydrogen levels or the oxygen levels fall outside a safe range.

Utilizing sensor data from the first injection port (upstream port) and second injection port (downstream port) allows for real-time adjustments to the downstream reactant gas. This helps optimize the abatement process, reducing or neutralizing harmful byproducts or emissions efficiently. The first sensors 290 at the first injection point measure the concentration of the primary reagent (e.g., H₂ or O₂) and pollutants (e.g., F₂, Cl₂). This data shows the initial conditions, indicating if sufficient reagents are being added to interact with the pollutants before the abatement system 120. The second sensors 295 at the second injection point provide measurements after the primary reaction occurs in the abatement system 120, showing remaining pollutants or partially reacted byproducts. This data identifies if further treatment is valuable, guiding the dosage and composition of the second reagent gas. Temperature data and pressure data may provide insight into how well the first reaction conditions support effective pollutant breakdown (at the first injection port). Temperature data and pressure data may provide post-reaction conditions (at the second injection point). Higher temperatures may indicate incomplete reactions or secondary reactions that need quenching with the downstream reagent.

Sensor data may be continuously fed into a closed-loop feedback control system that assesses pollutant levels, reagent ratios, and temperature/pressure conditions. The control system may use algorithms to decide how much of the downstream reagent gas is needed based on current exhaust conditions. If the first sensors 290 and the second sensors 295 detect elevated levels of byproducts or unreacted pollutants downstream, the control system can adjust the downstream reagent gas flow. Based on sensor feedback, the system can adjust not only the rate but also the composition of the downstream reagent. For instance, H2 or O2 may be varied if reactions produce mixed byproducts like HF or HCl. Using a set target concentration for each pollutant, the control system varies the reagent mix to achieve optimal pollutant neutralization with minimal excess.

In other examples, the system can use historical sensor data and trends to predict changes in exhaust composition and preemptively adjust downstream reagent injection before harmful levels are detected. The system may log all sensor data over time, allowing for analysis of trends, reagent usage, and abatement efficiency. Insights from logged data help refine reagent injection settings, improving system efficiency and reducing reagent consumption.

If harmful byproducts reach unsafe levels or sensor data indicates excessive reagent concentrations, the system can initiate automatic shutdowns or safety alarms. Alerts or notifications are set for pollutants or pressure build-up, allowing operators to manually intervene if needed.

The abatement system 120 thus ensures that downstream reagent gas is continuously and accurately adjusted based on real-time exhaust conditions, minimizing emissions and maximizing reagent efficiency.

In this setup, two reagent gases are used, one introduced before the abatement system 120 and a second injected after the abatement system 120. This setup manages their interaction while achieving desired pollutant removal. Stated differently, the dual-stage reagent injection method optimizes emissions control by tuning the chemistry at each exhaust phase, targeting harmful byproducts to ensure safe, clean emissions.

The first reagent gas, injected before the abatement system 120, is used to pre-treat or neutralize specific pollutants, preparing them for more effective abatement. Examples of first reagent gases include H₂, O₂ and/or H₂O. H₂ is often used to reduce reactive gases such as fluorine (F₂) or chlorine (Cl₂). O₂ can be introduced to oxidize combustible gases, breaking them into less harmful species for downstream processing.

The second reagent gas (e.g., foreline gas), injected after the plasma source 130 of the abatement system 120, further treats the exhaust or completes the reaction started by the first reagent, enhancing abatement efficiency. Examples of foreline gases include N₂, H₂ and O₂ . O₂ is used when the first reagent (such as H₂) produces reactive intermediates that demand further oxidation. H2 often follows oxidation to reduce any remaining oxidized intermediates into benign byproducts.

The abatement system 120 elevates exhaust temperatures, facilitating rapid reaction when the second reagent is injected downstream. To control the reaction rates and ensure safe handling, the injection rates of both reagents are closely monitored, ensuring they are neither excessive nor insufficient for complete reactions.

Both the pre-abatement reagent gases and post-abatement reagent gases have separate, controlled injection ports with sensors to monitor flow rates and concentrations, ensuring balanced and controlled interactions.

This dual-reagent approach is advantageous for systems with complex pollutants, as it allows staged and controlled reactions to ensure maximum pollutant neutralization while minimizing hazardous byproducts.

The reactions between the first and second reagent gases may depend on exhaust temperature and pressure. For certain reactions, a higher temperature (e.g., above 250° C.) will facilitate rapid conversion, especially in post-abatement reactions. Maintaining a stable pressure across both the pre-pump and post-pump sections is beneficial for consistent reagent flow rates, enabling complete reactions.

Data from gas sensors, thermocouples, and flow meters can be fed into a control system that adjusts reagent injection rates in real-time. For instance, if F₂ concentration is higher than expected downstream, the system can increase H₂ injection until it is neutralized. PIDs may be used to stabilize parameters like flow rate and temperature, ensuring that reagent gas injections maintain optimal reaction conditions without manual adjustments. Safety interlocks may also be used. For example, if gas concentrations (e.g., H₂ or O₂) exceed safe limits, automated shutoff valves can halt injection to prevent hazardous reactions. Threshold-based alarms for specific gases, temperatures, or pressures provide immediate notifications if conditions are outside safe ranges, prompting manual or automated corrective actions. Continuous data logging may be enabled to record sensor readings and reaction parameters over time. Some control systems may include reporting software that logs data on emissions for compliance and environmental audits, which can help refine the process for better efficiency.

The benefits of using a post-plasma reagent addition (e.g., oxygen or hydrogen), where reagent gases are introduced after the plasma abatement process include enhanced gas breakdown efficiency, optimized reagent use, reduced contamination and fouling, and improved system flexibility. In a post-plasma configuration, the plasma first dissociates harmful gases (like PFCs), breaking them into reactive fragments. Adding reagent gases after the plasma (e.g., oxygen or hydrogen) may enhance secondary reactions with these fragments, optimizing the neutralization of harmful byproducts. This can reduce the chance of reformation of F-GHGs and other hazardous compounds. Introducing reagents after the plasma dissociation may allow for more precise use of reagents, reacting only with the dissociated gas byproducts. This approach may reduce the amount of reagent gas needed compared to pre-plasma addition, lowering operational costs. By injecting reagent gases (e.g., oxygen or hydrogen) after the plasma, potential contamination or interaction between reagents and plasma-exposed surfaces may be minimized. This may reduce equipment fouling or degradation over time, leading to lower maintenance costs and improved system longevity. Post-plasma reagent addition may offer greater flexibility in reagent selection based on the specific byproducts generated during dissociation. It may also allow for fine-tuned control over the reagent delivery system, optimizing abatement for various semiconductor manufacturing processes.

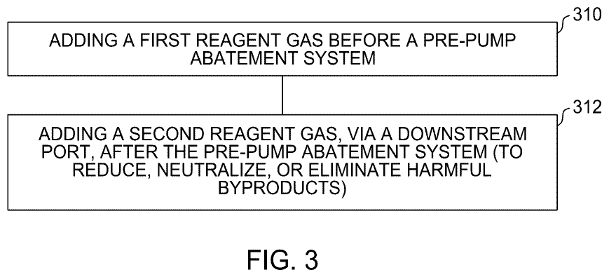

FIG. 3 is a flowchart for using a downstream port in the abatement system of FIG. 2, according to certain embodiments, according to an embodiment of the present application.

At operation 310, a first reagent gas is added to effluent flowing in a foreline coupled to a semiconductor processing chamber upstream of a plasma reactor. The first reagent gas may be a single gas, or a combination of two or more gases. The first reagent gas may include at least water vapor, oxygen, hydrogen, nitrogen, ammonia, argon, methane, carbon dioxide, or other suitable gas.

At operation 312, a foreline gas comprising a second reagent gas is added or disposed, via a downstream injection port, after the plasma reactor of the abatement system to reduce, neutralize, or eliminate harmful byproducts. By placing the downstream port directly after the pre-pump abatement unit, before temperatures drop, ensures the reaction takes place while the exhaust is still hot. The downstream port provides a location for introducing one or more reagents post-abatement, allowing for further reactions with residual gases. This flexibility enables adjustments to reagent types and flow rates based on the specific gas composition detected at this stage. The second reagent gas may include at least, oxygen, hydrogen, nitrogen, ammonia, argon, methane, carbon dioxide, or other suitable gas or other suitable gas.

In conclusion, a downstream port is utilized for introducing foreline reagent gases after the plasma reactor. The downstream port may be positioned directly after the plasma reactor upstream of the vacuum source. The upstream port before the plasma reactor of the abatement system provides a first reagent gas and the downstream port after the plasma reactor provides a second reagent gas. The second reagent gas and the first reagent gas interact with the processing chamber effluent in the foreline to minimize the environmental impact of the exhaust. The choice of the second reagent gas following the plasma reactor depends on the chemical characteristics and reactivity of the first reagent gas, the composition of the effluent exiting the processing chamber into the foreline, as well as the target byproducts for neutralization. Stated differently, the second reagent gas is chosen to work synergistically with the first reagent gas to target and neutralize specific byproducts. The second reagent gas can be, e.g., hydrogen, oxygen and other suitable gas. The second reagent may additionally include nitrogen to help manage the foreline gas pressures at the vacuum source.

When introducing elements of the present disclosure or exemplary aspects or embodiments thereof, the articles “a,” “an,” “the” and “said” are intended to mean that there are one or more of the elements.

The terms “comprising,” “including” and “having” are intended to be inclusive and mean that there may be additional elements other than the listed elements.

The term “coupled” is used herein to refer to the direct or indirect coupling between two objects. For example, if object A physically touches object B and object B touches object C, the objects A and C may still be considered coupled to one another—even if objects A and C do not directly physically touch each other. For instance, a first object may be coupled to a second object even though the first object is never directly in physical contact with the second object.

While the foregoing is directed to embodiments of the present disclosure, other and further embodiments of the disclosure may be devised without departing from the basic scope thereof, and the scope thereof is determined by the claims that follow.

What is claimed is:

1. A method for abating exhaust gases exiting a semiconductor processing system, the method comprising:
supplying a first gas into a first inlet port disposed in a foreline between a semiconductor processing chamber and a plasma source; and
supplying a second gas into a second inlet port disposed in the foreline between the plasma source and a vacuum source, wherein the second gas is one or both of a hydrogen containing gas and an oxygen containing gas.

2. The method of claim 1, wherein the first gas is hydrogen (H₂) and the second gas is oxygen (O₂).

3. The method of claim 2, wherein an interaction of the first gas with the second gas results in water vapor (H₂O).

4. The method of claim 1, wherein the second gas is H₂.

5. The method of claim 4, wherein a byproduct of an interaction of the second gas with gases downstream of the plasma source results in hydrogen fluoride (HF).

6. The method of claim 1, wherein the first inlet port is coupled to first sensors and the second inlet port is coupled to second sensors.

7. The method of claim 6, wherein data received from the first sensors and the second sensors is used to adjust levels or flow rates of the second gas.

8. The method of claim 6, wherein the second gas is adjusted based on historical sensor data.

9. A method for abating exhaust gases exiting a semiconductor processing system, the method comprising:
supplying a gas into an inlet port disposed in a foreline between a plasma source and a vacuum source; and
coupling the foreline to at least one of a hydrogen containing gas source or an oxygen containing gas source.

10. The method of claim 9, wherein the gas is hydrogen (H₂).

11. The method of claim 10, wherein the H₂ interacts with a byproduct to generate hydrogen fluoride (HF).

12. The method of claim 9, wherein the gas is oxygen (O₂).

13. The method of claim 12, wherein the O₂ interacts with a byproduct to generate water vapor (H₂O).

14. The method of claim 9, wherein the inlet port is coupled to sensors.

15. The method of claim 14, wherein data received from the sensors is used to adjust levels or flow rates of the gas supplied to the inlet port.

16. The method of claim 14, wherein the gas is adjusted based on historical sensor data.

17. An abatement device, comprising:
a plasma reactor;
a first conduit coupled to an inlet of the plasma reactor;
a reagent source coupled to an upstream injection port of the first conduit;
a second conduit coupled to an outlet of the plasma reactor having at least one downstream injection port positioned downstream of the plasma reactor; and
a foreline gas injection kit coupled to the second conduit through the at least one downstream injection port, the foreline gas injection kit coupled to at least one of a hydrogen containing gas source or an oxygen containing gas source.

18. The abatement device of claim 17, wherein the hydrogen containing gas source is configured to provide hydrogen (H₂).

19. The abatement device of claim 18, wherein the oxygen containing gas source is configured to provide oxygen (O₂).

20. The abatement device of claim 18, wherein the reagent source is configured to provide O₂ and water vapor (H₂O) to the upstream injection port.
